(19) United States
(12) Patent Application Publication
(10) Pub. No.: US 2018/0062479 A1
(43) Pub. Date: Mar. 1, 2018

(54) Modular Vehicle Engine Component Actuator

(71) Applicant: CTS Corporation, Lisle, IL (US)

(72) Inventors: William S. Stewart, Elkhart, IN (US); Yi Sheng, Clarence Center, NY (US); Lei Zhao, Elkhart, IN (US)

(73) Assignee: CTS Corporation, Lisle, IL (US)

(21) Appl. No.: 15/683,865

(22) Filed: Aug. 23, 2017

Related U.S. Application Data
(60) Provisional application No. 62/379,057, filed on Aug. 24, 2016.

(51) Int. Cl. H02K 7/08; F16H 3/66; H02K 1/27; H02K 21/24; H05K 1/18

(52) U.S. Cl. CPC H02K 7/083; F16H 3/66; H02K 7/085; G01R 15/202; H02K 21/24; H05K 1/18; H02K 1/2793

(57) ABSTRACT

A modular vehicle engine component actuator comprising a first module including a motor, a printed circuit board, and a motor shaft. A second module includes a gear train and an output shaft. The first module is coupled to the second module in a relationship with the motor shaft extending into the second module and into coupling relationship with the gear train in the second module. The first and second modules define respective first and second openings and interior cavities in communication with each other. The first and second modules are coupled together in a relationship with the printed circuit board positioned between the motor in the first module and the gear train in the second module. The motor shaft extends through a hole in the printed circuit board and into coupling relationship with the gear train in the second module.

### CROSS-REFERENCE TO RELATED APPLICATION

This patent application claims priority and benefit of the filing date of U.S. Provisional Patent Application Ser. No. 62/379,057 filed on Aug. 24, 2016, the disclosure and contents of which is expressly incorporated herein in its entirety by reference.

### FIELD OF THE INVENTION

This Invention relates to an actuator and, more specifically, to a modular vehicle engine component actuator.

### BACKGROUND OF THE INVENTION

Actuators are used in equipment such as vehicles to actuate vehicle engine components including for example engine valves or vehicle engine turbocharger vanes.

The present invention is directed to a modular vehicle engine component actuator with separate motor and gear modules.

### SUMMARY OF THE INVENTION

The present invention is generally directed to a modular vehicle engine component actuator comprising a first module including a motor, a printed circuit board, and a motor shaft housed therein and a second module including a gear train and an output shaft housed therein, the first module being coupled to the second module in a relationship with the motor shaft in the first module extending into the interior of the second module and into coupling relationship with the gear train in the second module.

In one embodiment, the first and second modules define respective first and second openings and interior cavities, the first and second modules being coupled in a relationship with the respective first and second openings and interior cavities in communication with each other.

In one embodiment, the first and second modules are coupled together in a relationship with the printed circuit board positioned between the motor in the first module and the gear train in the second module.

In one embodiment, the printed circuit board defines a through-hole, the motor shaft extending through the through-hole and into the interior of the second module into coupling relationship with the gear train in the second module.

In one embodiment, the gear train in the second module includes a ring gear assembly and first and second planet gear assemblies located in the interior of the ring gear assembly, the motor shaft being coupled to the first planet gear assembly and the output shaft being coupled to the second planet gear assembly.

In one embodiment, a return spring surrounds the ring gear assembly.

In one embodiment, the return spring includes a first end coupled to the second gear assembly and a second end coupled to the ring gear assembly.

In one embodiment, each of the ring gear assembly and the second gear assembly includes a plate, the first and second ends of the return spring being coupled to the respective plates of the ring gear assembly and the second gear assembly.

In one embodiment, the second module includes first, second, and third gears, the first and second gears being coupled to and for rotation relative to a plate in the second module, and the third gear is coupled to the output shaft, and the output shaft including one end coupled to and for rotation relative to the plate, the motor shaft being coupled to first gear, the first gear being coupled to the second gear, and the second gear being coupled to the third gear.

The present invention is also directed to a modular vehicle engine component actuator comprising a first module defining a first opening and a first interior cavity in communication with the first opening and including a motor, a printed circuit board defining a through-hole, and a motor shaft extending through the through-hole in the printed circuit board and a second module defining a second opening and a second interior cavity in communication with the second opening and including one or more gears and an output shaft, wherein the first and second modules are coupled together in a relationship with the first and second openings and the first and second interior cavities in communication with each other and with the motor shaft extending into the second interior cavity into coupling relationship with the one or more gears and the printed circuit board in the first module separating the motor in the first module from the one or more gears in the second module.

In one embodiment, the printed circuit board defines a through-hole, the motor shaft extending through the through-hole and into the second interior cavity of the second module.

In one embodiment, the one or more gears includes planet gears and a ring gear surrounding the planet gears, the motor shaft extending into the ring gear and coupled to the planet gears, the output shaft being coupled to the planet gears.

In one embodiment, the one or more gears includes first and second gears mounted for rotation on a support plate and a third gear mounted to the output shaft, the motor shaft being coupled to the first gear.

The present invention is further directed to a modular vehicle engine component actuator comprising a first module including a first housing defining a first interior cavity for a motor, a printed circuit board, and a motor shaft and a second module including a second housing defining a second interior cavity for one or more gears and an output shaft, the first and second modules being coupled together in a relationship with the first and second interior cavities in communication with each other and the motor shaft extending into the second module into coupling relationship with the one or more gears in the second module, the printed circuit board separating the motor in the first module from the one or more gears in the second module.

Other advantages and features of the present invention will be more readily apparent from the following detailed description of the preferred embodiments of the invention, the accompanying drawings, and the appended claims.

### BRIEF DESCRIPTION OF THE DRAWINGS

These and other features of the invention can best be understood by the description of the accompanying FIGS. as follows:

FIG. 1 is a perspective view of a modular vehicle engine component actuator in accordance with the present invention;

FIG. 2 is an exploded perspective view of the modular vehicle engine component actuator shown in FIG. 1;

FIG. 3 is a vertical cross-sectional view of the modular vehicle engine component actuator shown in FIG. 1;

FIG. 4 is a broken perspective view of the interior of the gear module of the modular vehicle engine component actuator of FIG. 1;

FIG. 5 is a perspective view of another embodiment of a modular vehicle engine component actuator in accordance with the present invention;

FIG. 6 is an exploded perspective view of the modular vehicle engine component actuator shown in FIG. 5; and

FIG. 7 is a vertical cross-sectional view of the modular vehicle engine component actuator shown in FIG. 5.

### DESCRIPTION OF THE EMBODIMENTS

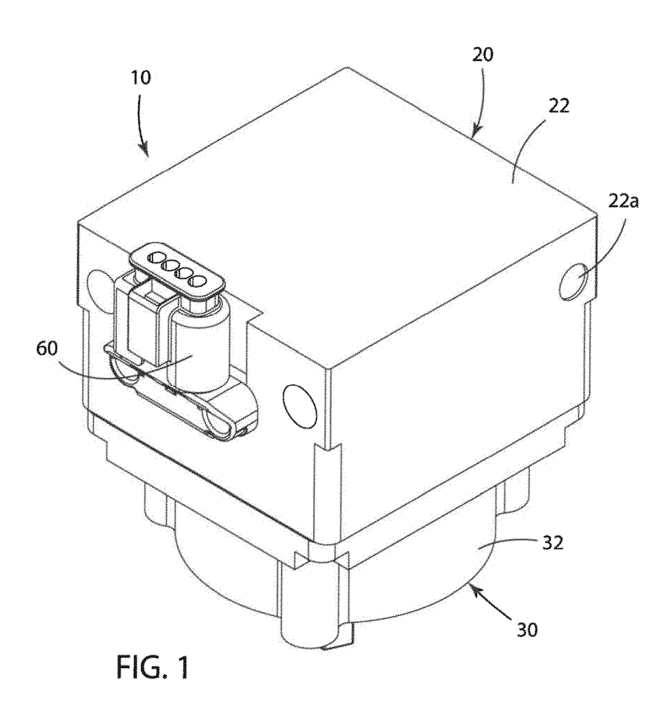

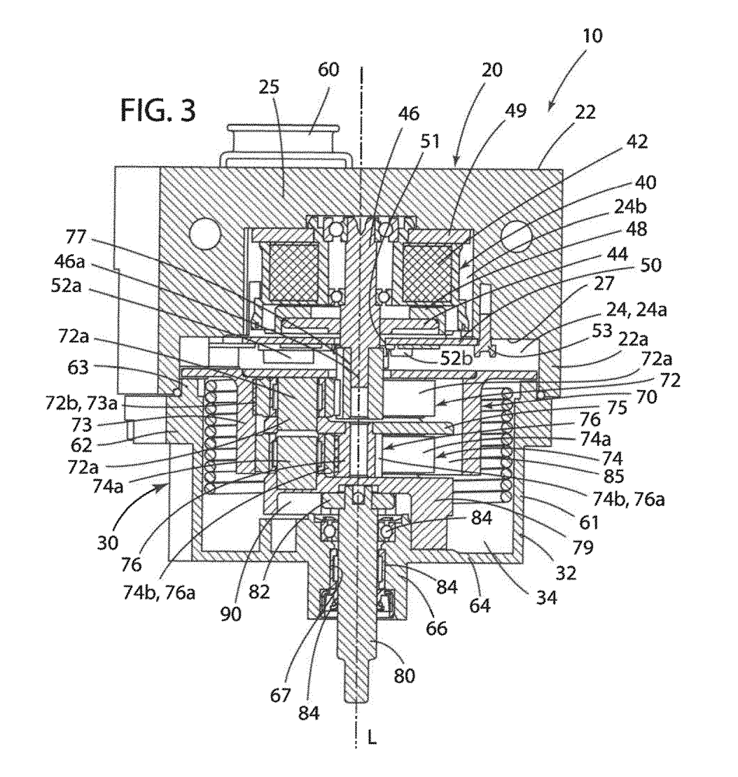

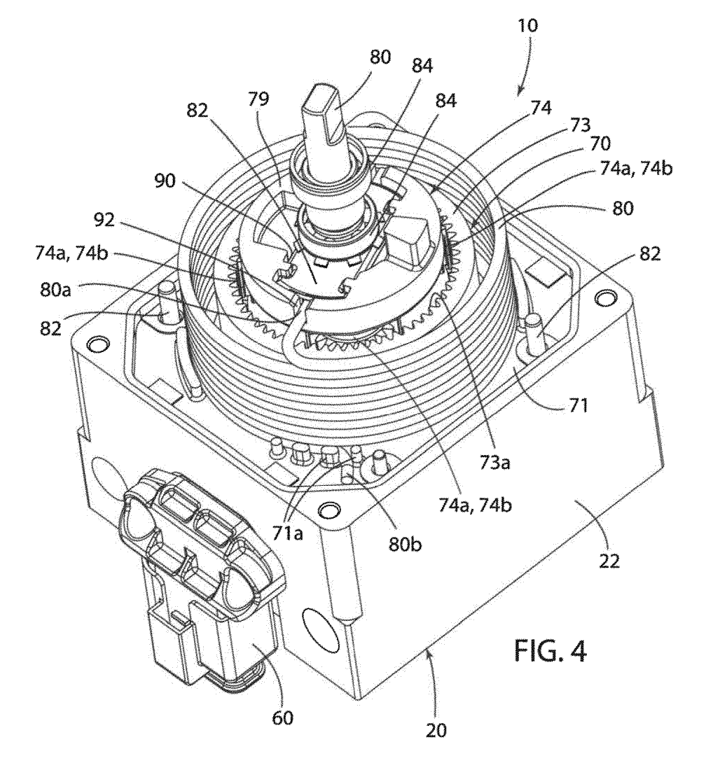

FIGS. 1-4 depict a modular actuator 10 in accordance with the present invention which, in the embodiment shown, is a modular actuator 10 adapted to actuate a vehicle component such as for example an engine valve or the vanes of a turbocharger in a motor vehicle engine.

The modular actuator 10 is comprised of separate first and second actuator modules 20 and 30 which are coupled together to define the actuator 10. In the embodiment shown, each of the first and second actuator modules 20 and 30 includes respective housings 22 and 32 defining respective interior housing cavities 24 and 34 respectively.

The interior housing cavity 24 of the housing of the module 20 in turn defines first and second interior cavity sections 24a and 24b respectively. The interior cavity section 24b is defined in part by an interior wall 25 extending in a direction generally normal to the vertical longitudinal axis L of the actuator 10. The interior cavity 24a is defined in part by an interior wall 27 extending in a direction generally normal to the longitudinal axis L and generally parallel and spaced from the interior wall 25.

In the embodiment shown, a first end of the housing 22 and module 20 defines an opening in communication with the interior cavity 24 and, more specifically, the interior cavity section 24a which in turn opens into the interior cavity section 24b which in turn is closed by the interior wall 25 which defines the ceiling or roof or closed end of the housing 22 and the module 20. The housing 22 includes a circumferential exterior wall 22a.

An expansion plug 22b covers a through-hole 22c defined in the circumferential exterior wall 22a of the housing 22.

The first actuator module 20 comprises the actuator motor module and is adapted to house an electric motor 40 and, more specifically, an axial electric brushless DC motor of the type and construction disclosed in for example US Published Patent Application No. US2016/0241107 to King et al., the description of which is incorporated herein by reference as though fully set forth herein.

The motor 40 includes a stator assembly 42, a rotor assembly 44, and a motor shaft 46 extending through the center of the stator assembly 42 and into coupling relationship with the rotor assembly 44. The rotor assembly 42 includes a disc shaped magnet 48 mounted thereto. The rotor assembly 42 and motor shaft 46 are adapted for rotation relative to the stator assembly 42.

The motor 40 and, more specifically, the stator assembly 42 thereof, is mounted to a motor mounting bracket 49. The motor 40 is located and mounted in the interior cavity section 24b of the interior cavity 24 of the module 20 in a relationship with the bracket 49 mounted to the interior face of the housing wall in a relationship generally normal to the actuator longitudinal axis L and with the motor shaft 46 extending in a relationship generally co-linear with the actuator longitudinal axis L. A plurality of screws 49a mount the bracket 49 to the interior housing wall 25.

The motor module 20 further comprises a printed circuit board 50 that includes a plurality of electrical components such as, for example, the components 52a, 52b, and 52c mounted to one or both of the opposed exterior surfaces thereof including a Hall effect sensor IC 52b. The printed circuit board 50 defines a central through aperture 51 for the motor shaft 46.

A plurality of cap screws 53 mount the printed circuit board 50 in the interior cavity section 24a to the interior face of the housing wall 27 in a relationship with the peripheral edge of the printed circuit board 50 abutted against and secured to the periphery of the interior housing wall 27; the printed circuit board 50 positioned and extending across the opening defined between the respective interior cavity sections 24a and 24b; the printed circuit board 50 extending in a relationship generally normal to the actuator longitudinal axis L; and the end of the motor shaft 46 extending through the interior housing section 24b, through the central through aperture 51 in the printed circuit board 50, and into the interior cavity section 24a.

The first actuator module 20 additionally includes an electrical connector 80 projecting outwardly from the exterior wall 22a of the housing 22 of the module 20 and including electrical contact terminals 60b adapted for electrical coupling relationship with the printed circuit board 50. Connector wires (not shown) couple the connector 60 to an engine controller (not shown).

A plurality of cap screws 60a mount the connector 60 to the exterior wall 22a of the housing 22 of the module 20.

The second actuator module 30 comprises the torque transmission gearbox/gear train/customer interface actuator module which, in the embodiment shown, houses one or more gears and an actuator output shaft 80 as described in more detail below.

The housing 32 of the module 30 includes a circumferential exterior wall 61 with a circumferential distal shoulder 62 and a circumferential lip 63 protruding outwardly from a peripheral radial end face of the distal shoulder 62.

The housing 32 defines an opening at the end thereof that includes the circumferential lip 63 and is in communication with the interior cavity 34. The housing 32, and thus the module 30, also includes a lower floor wall 64 that forms and defines a closed end of the housing 32 and thus the module 30. The lower floor wall 64 extends in a direction normal to the actuator longitudinal axis L and includes a central cylindrical sleeve 86 defining an interior through-hole 67.

The actuator output shaft 80 extends through the through-hole 67 defined in the sleeve 66 in a relationship co-linear with both the actuator longitudinal axis L and the motor shaft 46. A bracket 82 is secured to one end of the actuator output shaft 80. A plurality of bearings and seals, generally designated with the same numeral 84, mount and seal the actuator output shaft 80 in the interior sleeve 66 for rotation relative to the sleeve 66.

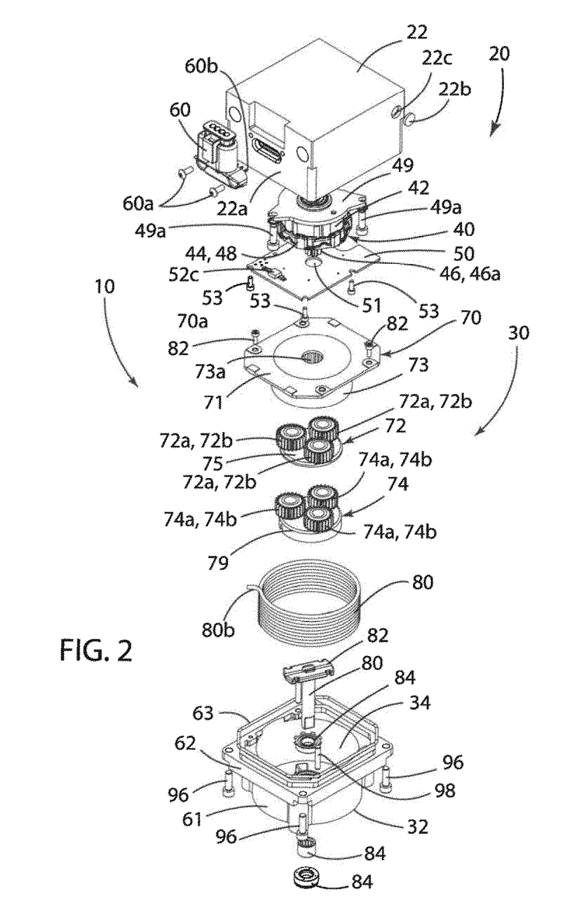

Referring to FIGS. 2-4, the module 30 also houses a gear train including a plurality of gears/gear assemblies 70, 72, 74, 76, and 77 as described in more detail below.

In the embodiment shown, the gear assembly 70 includes a stationary ring gear 73 coupled to and for rotation relative to a gear carrier plate bracket 71. The carrier plate bracket 71 includes at least a first pair of spaced apart prongs or fingers 71a projecting outwardly from a lower exterior face thereof and defining an open slot therebetween for receiving an end 80b of a return spring 80 as described in more detail below.

The first stage gear assembly 72 includes a first set of three rotatable planet gears 72a mounted on, and for rotation relative to, a flat carrier plate 75. A collar gear 76 with exterior teeth 76a depends outwardly from a lower face of the carrier plate 75.

The second stage gear assembly 74 includes a second set of three rotatable planet gears 74a mounted on, and for rotation relative to, a disc shaped carrier plate 79. A lower face of the carrier plate 79 defines a bracket recess 90.

A plurality of screws 82 mount the carrier plate bracket 71 to the radial end face of the peripheral lip 62 of the housing wall 61 thereby mounting the ring gear assembly 70 in the interior cavity 34 of the module 30 in a relationship with the exterior circumferential wall of the ring gear 73 spaced from the exterior circumferential wall 61 of the module 30.

The gear assemblies 72 and 74 are located in the interior cavity 34 of the module 30 in a stacked relationship and, more specifically, are located in the interior of the ring gear 73 and, still more specifically, are located in the interior cavity 85 defined by the exterior circumferential wall of the ring gear 73.

Still more specifically, the gears 72a Include exterior teeth 72b in meshing relationship with interior teeth 73a formed on the interior surface of the circumferential wall of the ring gear 73. The gears 74 are disposed in a relationship opposed to the plate bracket 75 and surrounding and including exterior teeth 74a in meshing relationship with the exterior teeth 76a of the collar gear 76 depending from the plate bracket 75.

The bracket 82 of the actuator output gear 80 is seated and keyed into the groove or key hole 90 defined in the disc shaped plate 79 that mounts the gears 74a thus mounting the actuator output shaft 80 in a relationship generally co-linear with the actuator longitudinal axis L and the motor shaft 48.

The disc shaped plate 79 also defines a slot 92.

The gear 77 is a motor pinion gear that couples the toothed lower end of the motor shaft 46 to the gears 72a.

The module 30 further includes a helical return spring 80 that is located in the interior cavity 34 of the module 30 in a relationship surrounding and spaced from the ring gear 73 and, more specifically, in a relationship with the return spring 80 located between the interior surface of the exterior wall 61 of the housing 32 and the exterior surface of the circumferential wall of the ring gear 73.

The first and second actuator modules 20 and 30 are stacked against each other and coupled together in a relationship with the open ends of the respective modules 20 and 30 facing each other and, more specifically, in a relationship with the radial distal end face of the circumferential exterior wall 22a of the housing 22 of the module 20 abutted against the radial distal shoulder 62 of the housing 32 of the module 30 and the circumferential lip 63 projecting outwardly from the circumferential shoulder 62 extending into the interior cavity section 24a of the module 20; with the motor pinion gear 77 located in the interior cavity section 24a of the module 20 including a first end surrounding and including interior teeth in meshing relationship with exterior teeth on the distal end 46a of the motor shaft 46 and an opposed second end extending centrally between the three gears 72a and including exterior teeth in meshing relationship with the exterior teeth 72b of the gears 72a; and with the carrier plate 71 of the gear assembly 70 extending into the interior cavity section 24a of the module 20.

A plurality of cap screws 96 extend through the radial shoulder 62 on the module 30 and into the radial end face of the exterior wall 22a of the module 20 for coupling the modules 20 and 30 together.

Thus, in the embodiment of FIGS. 1-4 with the modules 20 and 30 coupled together, the motor 40 in the module 20 and the gears 70, 72, and 74 in the module 30 are disposed in an opposed and co-linear relationship with the printed circuit board 50 positioned in a relationship directly opposed and spaced from the carrier plate 71 of the gear assembly 70 and, more specifically, with the printed circuit board 50 located between and separating the motor 40 in the module 20 from the plurality of gears in the module 30.

Moreover, with the modules 20 and 30 coupled together, the respective module openings face each other with the interior cavities 24 and 34 in communication with each other.

In accordance with the operation of the actuator 10, actuation of the motor 40 in the interior of the first actuator module 20 results in the rotation of the motor shaft 46 which results in the rotation of the motor pinion gear 77 which results in the rotation of the planet gears 72a coupled to the gear 77 which results in the rotation of the carrier plate 75 which results in the rotation of the collar gear 76 that depends from the carrier plate 75 which results in the rotation of the gears 74a coupled to the gear 76 which results in the rotation of the carrier plate 79 which results in the rotation of the output shaft bracket 82 coupled to the plate 79 which results in the rotation of the output shaft 80 which results in the activation or movement of the vehicle engine component (not shown but including for example a valve or turbocharger vanes) operably associated with and connected to the lower end of the output gear shaft 80.

Further, in accordance with the operation of the actuator 10, the rotation of the rotor 44 of the motor 40 results in the rotation of the magnet 48 which results in a change in the magnitude and/or direction of the magnetic field generated by the motor magnet 48 which is sensed by the Hall effect sensor 52b to allow the position of the rotor 44, and thus the position of the vehicle engine component operably connected thereto via the motor shaft 46 and gears 70, 72, and 74 to be determined.

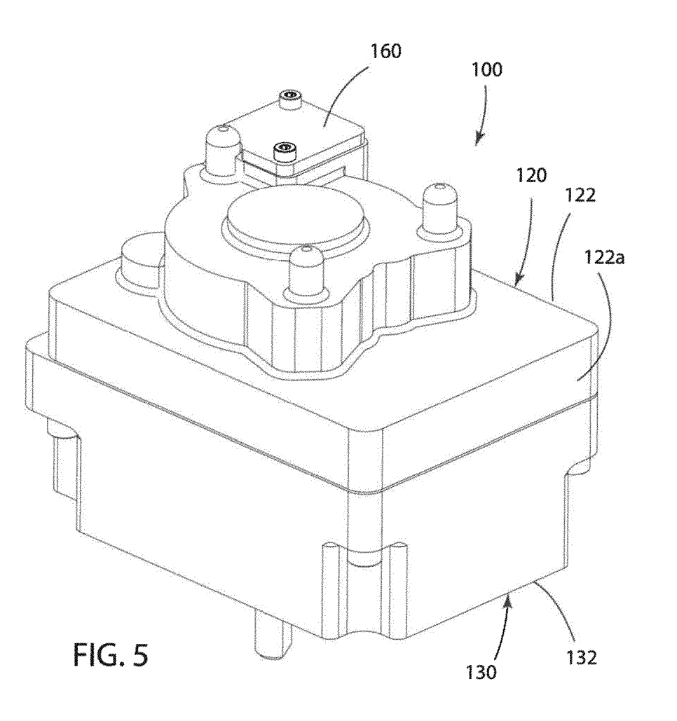

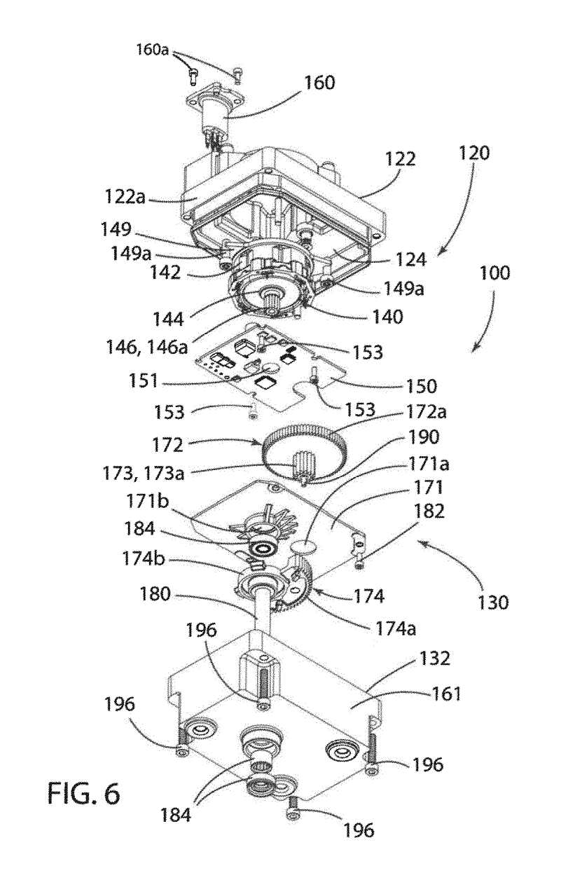

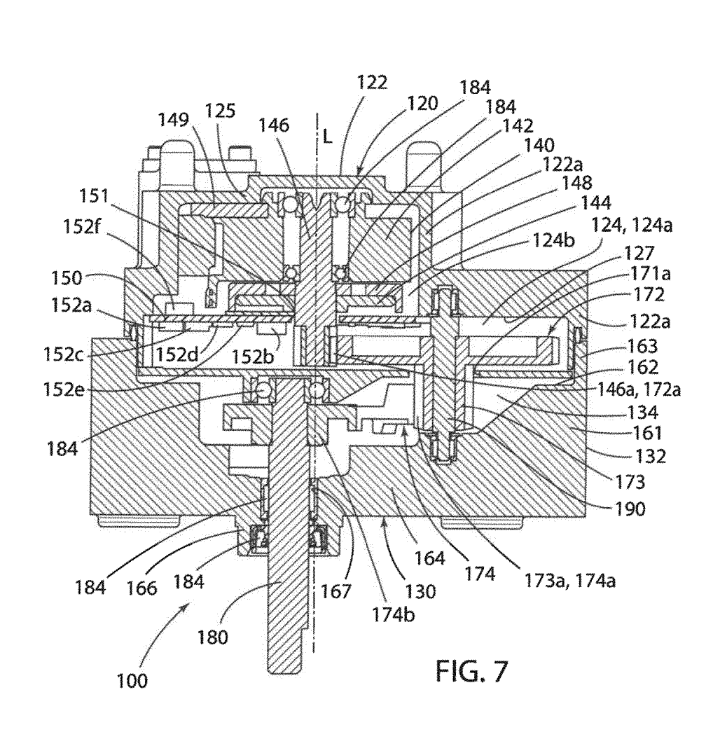

FIGS. 5-7 depict another embodiment of a modular vehicle engine component actuator 100 in accordance with the present invention.

The modular actuator 100 is comprised of first and second actuator modules 120 and 130 which are coupled together to define the actuator 100. In the embodiment shown, each of the first and second actuator modules 120 and 130 includes respective housings 122 and 132 defining respective interior housing cavities 124 and 134 respectively.

The interior housing cavity 124 of the housing 122 of the module 120 in turn defines first and second interior cavity sections 124a and 124b respectively.

The interior cavity section 24b is defined in part by an interior wall 125 extending in a direction generally normal to the vertical longitudinal axis L of the actuator 110. The interior cavity 124a is defined in part by an interior wall 127 extending in a direction generally normal to the longitudinal axis L and generally parallel and spaced from the interior wall 125.

In the embodiment shown, a first end of the housing 122 and module 120 defines an opening in communication with the interior cavity 124 and, more specifically, in communication with the interior cavity section 124a which in turn opens into the interior cavity section 124b which in turn is closed by the interior wall 125 which defines the ceiling or roof or closed end of the housing 122 and the module 120. The housing 122 includes a circumferential exterior wall 122a.

The first actuator module 120 comprises the actuator motor module and is adapted to house an electric motor 140 and, more specifically, an axial electric brushless DC motor of the type and construction disclosed in for example US Published Patent Application No. US2016/0241107 to King et al., the description of which is incorporated herein by reference as though fully set forth herein.

The motor 140 includes a stator assembly 142, a rotor assembly 144, and a motor shaft 146 extending through the center of the stator assembly 142 and into coupling relationship with the rotor assembly 144. The rotor assembly 142 includes a disc shaped magnet 148 mounted thereto. The rotor assembly 142 and motor shaft 146 are adapted for rotation relative to the stator assembly 142.

The motor 140 and, more specifically, the stator assembly 142 thereof. Is mounted to a motor mounting bracket 149. The motor 140 is located and mounted in the interior cavity section 124b of the interior cavity 124 of the module 120 with the bracket 149 mounted to the interior face of the housing wall 125 in a relationship generally normal to the actuator longitudinal axis L and with the motor shaft 146 extending in the same direction as the actuator longitudinal axis L. A plurality of screws 149a mount the bracket 149 to the interior housing wall 125.

The motor module 120 further comprises a printed circuit board 150 that includes a plurality of electrical components such as, for example, the components 152a-152e mounted to one or both of the opposed exterior surfaces thereof including a Hall Effect sensor IC 152b. The printed circuit board 150 defines a central through aperture 151 for the motor shaft 146.

A plurality of cap screws 153 mount the printed circuit board 150 in the interior cavity section 124a to the interior face of the housing wall 127 in a relationship with the peripheral edge of the printed circuit board 150 abutted against and secured to the interior housing wall 127; the printed circuit board 150 positioned and extending across the opening defined between the respective interior cavity sections 124a and 124b; the printed circuit board 150 extending in a relationship generally normal to the actuator longitudinal axis L; and the end of the motor shaft 146 extending through the interior housing section 124b, the central through aperture 151 in the printed circuit board 150, and into the interior cavity section 124a.

The first actuator module 120 additionally includes an electrical connector 160 projecting outwardly from the exterior wall 122a of the housing 122 of the module 120 and including electrical contact terminals 160b adapted for electrical coupling relationship with the printed circuit board 150. Connector wires (not shown) couple the connector 60 to an engine controller (not shown).

A plurality of cap screws 160a mount the connector 160 to the exterior wall 122a of the housing 122 of the module 120.

The second actuator module 130 comprises the torque transmission gearbox/geartrain/customer interface actuator module which, in the embodiment shown, houses a plurality of gears and an actuator output shaft 180 as described in more detail below.

The housing 132 of the module 130 includes a circumferential exterior wall 161 with a circumferential distal shoulder 162 and a circumferential lip 163 protruding outwardly from a peripheral radial end face of the distal shoulder 162.

The housing 132 is open at the end thereof that includes the circumferential lip 163 and, more specifically opens into and is in communication with the interior cavity 134 thereof. The housing 132, and thus the module 130, also includes a lower floor wall 164 that forms and defines a closed end of the housing 132 and thus the module 130. The lower floor wall 164 extends in a direction normal to the actuator longitudinal axis L and includes a central cylindrical sleeve 166 defining an interior through-hole 167.

The actuator output shaft 180 extends through the through-hole 167 defined in the sleeve 166 in a relationship parallel to both the actuator longitudinal axis L and the motor shaft 146. A plurality of bearings and seals, generally designated with the same numeral 184, mount and seal the actuator output shaft 180 in the interior sleeve 166 for rotation relative to the sleeve 166.

Referring to FIGS. 2-4, the module 130 also houses a plurality of gears/gear assemblies 172, 173, and 174 as described in more detail below.

In the embodiment shown, the gear 172 is an intermediate circle gear with exterior teeth 172a and the gear 173 is a collar gear with exterior teeth 173a and which depends downwardly from the center of the circle gear 172.

The gear 174 is an output sector gear with exterior teeth 174a. A bracket 174b couples the gear 174 to one end of an output shaft 180.

The module 130 also includes a gear support plate 171 defining a through aperture 171a and a bracket 171b projecting from a lower face thereof.

The gear plate 171 is located and mounted in the interior cavity 134 of the module 130 and, more specifically, is located and mounted in the interior cavity 134 with a peripheral circumferential edge thereof seated and mounted to the interior peripheral wall 162 of the housing 132 of the module 130 in a relationship generally normal to the actuator longitudinal axis L.

The gears 172 and 173 are located and mounted in the interior cavity 134 of the module 130 in a relationship with the gear 172 seated on and rotatable relative to the top exterior face of the gear plate 171 and the gear 173 extending through the through hole 171a defined in the gear plate 171.

The gear 174 includes a mounting bracket 174b surrounding an end of the output shaft 180 that extends into the bracket 171b projecting outwardly from the lower face of the gear support plate 171. The output shaft 180 extends through the interior cavity 134 of the module 130 in a relationship spaced from and generally parallel to both the motor shaft 148 and the actuator longitudinal axis L. The end of the output shaft 180 opposite the end thereof coupled to the gear plate 171 extends through the interior of the sleeve 166. The output shaft 180 is rotatable relative to the gear support plate 171 and the sleeve 166.

The first and second actuator modules 120 and 130 are stacked against each other and coupled together in a relationship with the open ends of the respective modules 120 and 130 facing each other and the respective interior cavities 124 and 134 in communication with each other and, more specifically, in a relationship with the radial distal end face of the circumferential exterior wall 122a of the housing 122 of the module 120 abutted against the radial distal face of the lip 163 of the module 130; with the distal end of the rotatable motor shaft 146 extending into the interior cavity 134 of the module 130 and including exterior teeth 146a in meshing relationship with exterior teeth 172a of the gear 172; and with exterior teeth 173a of the gear 173 in meshing relationship with exterior teeth 174a of the sector gear 174.

The gears 172 and 173 are mounted for rotation on an elongate shaft 190 that extends through the through aperture 171a defined in the gear plate 171 and includes respective ends mounted in the interior wall 127 of the module 20 and the interior wall 164 of the module 130 respectively.

Thus, in the embodiment of FIGS. 5-7 with the modules 120 and 130 coupled together, the motor 140 in the module 120 and the gears 172, 173, and 174 in the module 130 are disposed in an opposed relationship with the printed circuit board 150 located between and separating the motor 140 in the module 120 from the plurality of gears 172, 173, and 174 in the module 130.

In accordance with the operation of the actuator 100, actuation of the motor 140 in the interior of the first actuator module 120 results in the rotation of the motor shaft 146 which results in the rotation of the gear 172 coupled to the motor shaft 146 which results in the rotation of the gear 173 which results in the rotation of the gear 174 coupled to the gear 173 which results in the rotation of the output shaft 180 coupled to the gear 174 which results in the activation or movement of the vehicle engine component (not shown but including for example a valve or turbocharger vanes) operably associated with and connected to the lower end of the output gear shaft 80.

Further, in accordance with the operation of the actuator 100, the rotation of the rotor 144 of the motor 140 results in the rotation of the magnet 148 which results in a change in the magnitude and direction of the magnetic field generated by the motor magnet 148 which is sensed by the Hall effect sensor 152b to allow the position of the rotor 144, and thus the position of the vehicle engine component operably connected thereto via the motor shaft 46 and gears 172, 173, and 174 to be determined.

In accordance with the present invention, the first actuator modules 20 and 120 are designed to be subject to a limited number of configurations. The second actuator modules 30 and 130 are designed to meet the torque/response time/resolution/mounting requirements of the customer on a per application basis.

In accordance with the present invention, the modular structure of the actuators 10 and 100 offers at least the following benefits: the respective first motor modules 20 and 120 and the respective second gear and output shaft modules 30 and 130 can be validated independently; the respective first motor modules 20 and 120 and the respective second gear and output shaft modules and 130 are subject to independent design and configuration depending on the application; the respective first motor modules 20 and 120 and the respective second gear and output shaft modules 30 and 130 are subject to mixing and matching to meet a variety of requirements; the commonality between the respective modules 20, 120, 30, and 130 reduces the per unit cost of the actuators 10 and 100; and any improvements to one or both of the respective first and second modules is subject to application across multiple actuator platforms.

In particular, the commonality in the design and configuration of the respective motor modules 20 and 120 and, more specifically, the commonality in the design and configuration of the motor components therein including respective motors 40 and 140 bracketed in respective interior module cavities 24 and 124; respective printed circuit boards 50 and 150 coupled to respective interior module walls 27 and 127; and respective motor shafts 46 and 146 extending into respective interior cavities 34 and 134 in respective gear modules 30 and 130 into coupling relationship with gears in a separate gear module allows the same basic motor module design to be used in a multitude of applications requiring different gear module designs.

In the same manner, the commonality in the design and configuration of the respective gear and output shaft modules 30 and 130 and, more specifically, the commonality in the design and configuration of gear modules including respective gear assemblies adapted for coupling relationship with the shaft of the motor extending in the interior cavity thereof allows the same basic gear module design (with the exception of the design of the particular gear chain) to be used in a multitude of applications.

Numerous variations and modifications of the modular vehicle engine component actuator embodiments described above may be effected without departing from the spirit and scope of the novel features of the invention. It is to be understood that no limitations with respect to the specific modular vehicle engine component actuator embodiments illustrated herein are intended or should be inferred. It is, of course, intended to cover by the appended claims all such modifications as fall within the scope of the claims.

What is claimed is:

1. A modular vehicle engine component actuator comprising:
a first module including a motor, a printed circuit board, and a motor shaft housed therein; and
a second module including a gear train and an output shaft housed therein, the first module being coupled to the second module in a relationship with the motor shaft in the first module extending into the interior of the second module and into coupling relationship with the gear train in the second module.

2. The modular vehicle engine component actuator of claim 1 wherein the first and second modules define respective first and second openings and interior cavities, the first and second modules being coupled in a relationship with the respective first and second openings and interior cavities in communication with each other.

3. The modular vehicle engine component actuator of claim 1 in which the first and second modules are coupled together in a relationship with the printed circuit board positioned between the motor in the first module and the gear train in the second module.

4. The modular vehicle engine component actuator of claim 1 wherein the printed circuit board defines a through-hole, the motor shaft extending through the through-hole and into the interior of the second module into coupling relationship with the gear train in the second module.

5. The modular vehicle engine component actuator of claim 1 wherein the gear train in the second module includes a ring gear assembly and first and second planet gear assemblies located in the interior of the ring gear assembly, the motor shaft being coupled to the first planet gear assembly and the output shaft being coupled to the second planet gear assembly.

6. The modular vehicle engine component actuator of claim 5 further comprising a return spring surrounding the ring gear assembly.

7. The modular vehicle engine component actuator of claim 6 wherein the return spring includes a first end coupled to the second gear assembly and a second end coupled to the ring gear assembly.

8. The modular vehicle engine component actuator of claim 7 wherein each of the ring gear assembly and the second gear assembly includes a plate, the first and second ends of the return spring being coupled to the respective plates of the ring gear assembly and the second gear assembly.

9. The modular vehicle engine component actuator of claim 1 wherein the second module includes first, second, and third gears, the first and second gears being coupled to and for rotation relative to a plate in the second module, and the third gear is coupled to the output shaft, and the output shaft including one end coupled to and for rotation relative to the plate, the motor shaft being coupled to first gear, the first gear being coupled to the second gear, and the second gear being coupled to the third gear.

10. A modular vehicle engine component actuator comprising:
a first module defining a first opening and a first interior cavity in communication with the first opening and including a motor, a printed circuit board defining a through-hole, and a motor shaft extending through the through-hole in the printed circuit board;
a second module defining a second opening and a second interior cavity in communication with the second opening and including one or more gears and an output shaft;
wherein the first and second modules are coupled together in a relationship with the first and second openings and the first and second interior cavities in communication with each other and with the motor shaft extending into the second interior cavity into coupling relationship with the one or more gears and the printed circuit board in the first module separating the motor in the first module from the one or more gears in the second module.

11. The modular vehicle engine component actuator of claim 10 wherein the printed circuit board defines a through-hole, the motor shaft extending through the through-hole and into the second interior cavity of the second module.

12. The modular vehicle engine component actuator of claim 10 wherein the one or more gears includes planet gears and a ring gear surrounding the planet gears, the motor shaft extending into the ring gear and coupled to the planet gears, the output shaft being coupled to the planet gears.

13. The modular vehicle engine component actuator of claim 10 wherein the one or more gears includes first and second gears mounted for rotation on a support plate and a third gear mounted to the output shaft, the motor shaft being coupled to the first gear.

14. A modular vehicle engine component actuator comprising:
a first module including a first housing defining a first interior cavity for a motor, a printed circuit board, and a motor shaft; and
a second module including a second housing defining a second interior cavity for one or more gears and an output shaft;
the first and second modules being coupled together in a relationship with the first and second interior cavities in communication with each other and the motor shaft extending into the second module into coupling relationship with the one or more gears in the second module, the printed circuit board separating the motor in the first module from the one or more gears in the second module.
